(19) United States
(12) Patent Application Publication
(10) Pub. No.: US 2011/0090020 A1
(43) Pub. Date: Apr. 21, 2011

(54) Voltage Controlled SAW Oscillator with Phase Shifter

(76) Inventor: GLEN O. REESER, PALATINE, IL (US)

(21) Appl. No.: 12/898,997

(22) Filed: Oct. 6, 2010

Related U.S. Application Data
(60) Provisional application No. 61/251,976, filed on Oct. 15, 2009.

(51) Int. Cl. H03B 5/30

(52) U.S. Cl. 331/155

(57) ABSTRACT

An oscillator which, in one embodiment, is a voltage controlled surface acoustic wave oscillator including at least a surface acoustic wave filter and a voltage controlled phase shifter. In one embodiment, the phase shifter includes at least one low pass circuit and two high pass circuits coupled in series to improve phase shift versus control voltage linearity. In one embodiment, the low pass circuit includes at least a pair of inductors in series and a variable resistor coupled in parallel therebetween and to ground and the high pass circuit includes at least a pair of variable resistors in series and an inductor coupled in parallel therebetween and to ground.

### CROSS-REFERENCE TO RELATED AND CO-PENDING APPLICATIONS

This application claims the benefit of the filing date of U.S. Provisional Patent Application Ser. No. 61/251,976 filed on Oct. 15, 2009 and entitled, “Voltage Controlled SAW Oscillator with Phase Shifter”, the entire disclosure of which is explicitly incorporated herein by reference as are all references cited therein.

### FIELD OF THE INVENTION

The invention is directed generally to an oscillator and, more specifically, to a voltage controlled surface acoustic wave oscillator with a phase shifter.

### BACKGROUND OF THE INVENTION

Oscillators such as, for example, voltage controlled surface acoustic wave oscillators, are used in a variety of electronic devices and are characterized in that the oscillation frequency can be varied with an external voltage. Although surface acoustic wave oscillators available today have proven satisfactory, there continues to be a need for smaller size, lower cost, and higher performance oscillators including voltage controlled surface acoustic wave oscillators.

### SUMMARY OF THE INVENTION

The present invention is directed generally to an oscillator incorporating a filter and a phase shifter including means for adjusting both positive and negative phase shift and centering the frequency of the oscillator.

In accordance with the invention, in one embodiment, the oscillator is a voltage controlled surface acoustic wave oscillator with a surface acoustic wave filter and the means for adjusting both positive and negative phase shift comprises a phase shifter with at least one low pass circuit section and at least one high pass circuit section. In one embodiment, the phase shifter includes one low pass circuit section coupled in series between two high pass circuit sections.

Also, in one embodiment, the low pass circuit section of the phase shifter includes at least a pair of inductors in series and a varactor/variable capacitor between the pair of inductors. The high pass circuit section of the phase shifter includes at least a pair of varactors/variable capacitors in series and an inductor between the pair of varactors/variable capacitors.

Other advantages and features of the present invention will be more readily apparent from the following detailed description of the preferred embodiment of the invention, the accompanying drawings, and the appended claims.

### BRIEF DESCRIPTION OF THE DRAWINGS

These and other features of the invention can best be understood by the following description of the accompanying FIGURES as follows:

FIG. 1 is a block diagram of a voltage controlled surface acoustic wave oscillator incorporating the features of the present invention;

FIG. 2 is a schematic diagram of one embodiment of the circuit of the voltage controlled phase shifter of the voltage controlled surface acoustic wave oscillator of the present invention;

FIG. 3 is a graph of the phase shift angle versus control voltage (Vt) performance of the voltage controlled surface acoustic wave oscillator of the present invention; and

FIG. 4 is a normalized representation of the graph of FIG. 3.

### DETAILED DESCRIPTION OF THE EMBODIMENT

While this invention is susceptible to embodiments in many different forms, this specification and the accompanying FIGURES disclose only one embodiment of an oscillator and, more specifically, a voltage controlled surface acoustic wave (SAW) oscillator in accordance with the present invention.

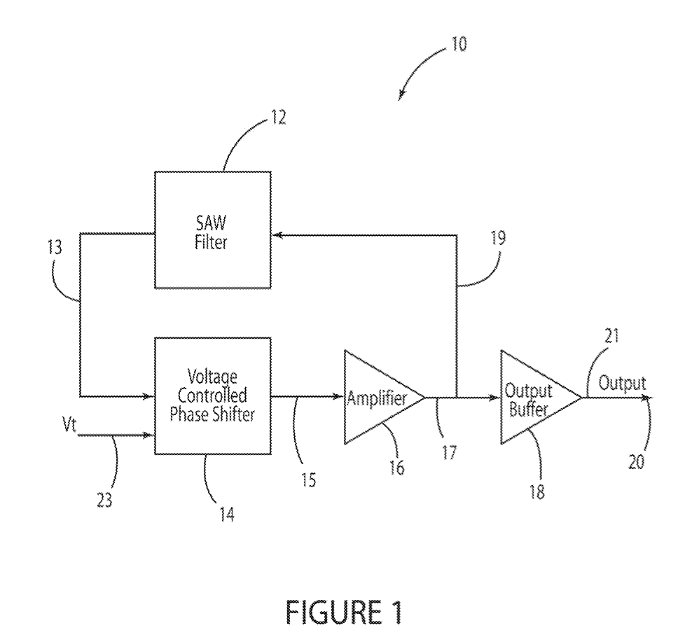

FIG. 1 is a block diagram of a voltage controlled surface acoustic wave (SAW) oscillator 10 which comprises the following elements: a surface acoustic wave filter (SAW filter) 12; a circuit line 13 which couples the output of the SAW filter 12 to the input of a voltage controlled phase shifter 14; a circuit line 15 which couples the output of the phase shifter 14 to the input of an amplifier 16; a circuit line 17 which couples the output of the amplifier 16 to the input of an output buffer 18; a circuit line 19 which is coupled to the circuit line 17 and couples the output of the amplifier 16 to the input of the SAW filter 12; and a circuit line 21 which couples the output of the buffer 18 to a frequency signal output 20.

Although not shown or described herein in any detail, it is understood that one or more of the oscillator elements identified above may be of either the discrete or integrated circuit type and are adapted to be mounted on a suitable printed circuit board or substrate measuring approximately either 5 mm in width by 7 mm in length or 9 mm in width by 14 mm in length. Moreover, and although not shown or described herein in any detail, it is understood that a sinewave-to-logic level translator circuit may be operably linked to the voltage controlled surface acoustic wave oscillator 10 and, more specifically, may be operably linked between the buffer 18 and the output 20 for generating a digital logic output signal.

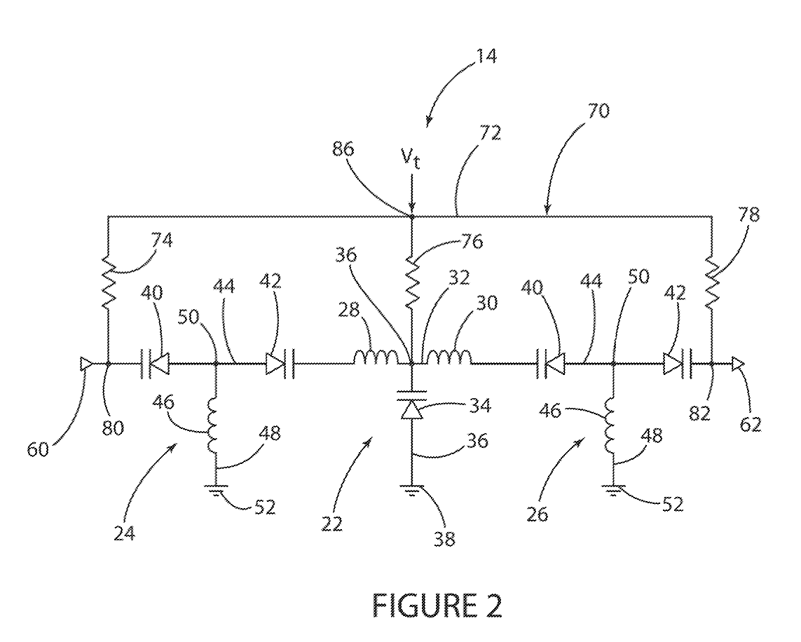

The SAW filter 12, the phase shifter 14, and the amplifier 16 in combination define the frequency signal generating feedback circuit or loop portion of the voltage controlled SAW oscillator 10. The phase shifter 14 defines the oscillator signal phase change/shift/adjustment section or circuit of the voltage controlled SAW oscillator 10. The magnitude of the phase change is in part dependent upon the value of the control voltage (Vt) which is inputted into the phase shifter 14 via the circuit line 23 depicted in FIG. 1. As shown in FIG. 2, the phase shifter 14 of the present invention comprises a multi-stage phase selection/mixing/shifting/adjustment means or circuit including a generally centrally located low pass negative phase shift circuit section or stage 22 and a pair of high pass positive phase shift sections or stages 24 and 26 coupled in series to respective opposite ends of the low pass circuit section 22. Thus, in the embodiment shown, the low pass circuit section 22 is coupled in series between and to the two high pass circuit sections 24 and 26 as described in more detail below.

The low pass circuit 22 includes a pair of inductors 28 and 30 coupled in series on a circuit line 32 and a varactor/variable capacitor 34 coupled in parallel to and between the inductors 28 and 30 and located on a circuit line 36 which, at one end, is coupled to the circuit line 32 at a point 36 thereon located between the inner ends of the inductors 28 and 30 and, at an opposite end, is coupled to ground 38.

Each of the high pass circuits 24 and 26 includes a pair of varactors/variable capacitors 40 and 42 coupled in series on a circuit line 44 and an inductor 46 coupled in parallel to the varactors/variable resistors 40 and 42 and located on a circuit line 48 which, at one end, is coupled to the circuit line 44 at a point 50 located between the anode ends of the varactors/variable capacitors 40 and 42 and, at an opposite end, is coupled to ground 52.

In the embodiment of FIG. 2, the circuit line 44 of the high pass circuit 24 is coupled in series to one end of the circuit line 32 of the low pass circuit 22, thereby coupling the cathode of the varactor/variable capacitor 42 of the high pass circuit 24 in series with one end of the inductor 28 of the low pass circuit 22. As also shown in FIG. 2, the circuit line 44 of the high pass circuit 26 is coupled in series to an opposite end of the circuit line 32 of the low pass circuit 22, thereby coupling the cathode of the varactor/variable capacitor 40 of the high pass circuit 26 in series with one end of the inductor 30 of the low pass circuit 22.

As further shown in FIG. 2, the phase shifter 14 additionally comprises a signal input 60 at the end of the circuit line 44 of the high pass circuit 24 opposite the end of the circuit line 44 coupled to the low pass circuit 22 and a signal output 62 at the end of the circuit line 44 of the high pass circuit 26 opposite the end of the circuit line 44 coupled to the low pass circuit 22. The signal input 60 is coupled to the cathode of the varactor/variable capacitor 40 of the high pass circuit 24. The signal output 62 is coupled to the cathode of the varactor/variable capacitor 42 of the high pass circuit 26.

Phase shifter 14 still further comprises a control voltage input circuit 70 (FIG. 2) including a circuit line 72 and three parallel resistors 74, 76, and 78.

One end of the resistor 74 is coupled to and extends from one end of the circuit line 72 while the other end of the resistor 74 is coupled to the circuit line 44 of high pass circuit 24 at a point 80 on the circuit line 44 located between the input 60 of the phase shifter 14 and the cathode of the varactor/variable capacitor 40 of the high pass circuit 24.

One end of the resistor 78 is coupled to and extends from an opposite end of the circuit line 72 while the other end of the resistor 78 is coupled to the circuit line 44 of the high pass circuit 26 at a point 82 on the circuit line 44 located between the output 62 of the phase shifter 14 and the cathode of the varactor/variable capacitor 42 of the high pass circuit 26.

One end of the resistor 76 is coupled to and extends from the middle of circuit line 72 while the other end of the resistor 76 is coupled to the circuit line 32 of the low pass circuit 22 at the point 36 located on the circuit line 32 between the inner ends of the pair of inductors 28 and 30 of the low pass circuit 22. The resistor 76 is located between, and in parallel with, the resistors 74 and 78.

Point 86 on the circuit line 72 defines the input for the control voltage Vt into the phase shifter 14. In the embodiment shown, the point 86 also defines the point at which the resistor 76 is coupled to the circuit line 72.

In accordance with the present invention, the use of a phase shifter 14, in a SAW oscillator, which combines and uses one or more low pass circuits 22 in combination with one or more high pass circuits 24 and 26 as described above provides the advantage of being able to choose the phase shift at a specific control voltage Vt, i.e., allows for the negative phase shift from one or more low pass circuits 22 and the positive phase shift from one or more high pass circuits 24 and 26 to be selected, mixed, and adjusted together to bring the center frequency to the proper tuning voltage thus eliminating the need to add static or fixed phase via either a transmission line, inductors, or capacitors of fixed value to center the frequency.

The combination, mixing, and adjustment of the negative and positive phase shifts respectively of the low pass and high pass circuits 22, 24, and 26 in the phase shifter 14 as described thus advantageously results in a SAW oscillator which will exhibit a more linear phase shift versus control voltage (Vt) performance and relationship, as opposed to SAW oscillators which combine only either high pass sections in series or low pass sections in series, i.e., respective combinations which result in an increase in non-linearity and require the addition of static or fixed phase to bring the center frequency to the proper tuning voltage.

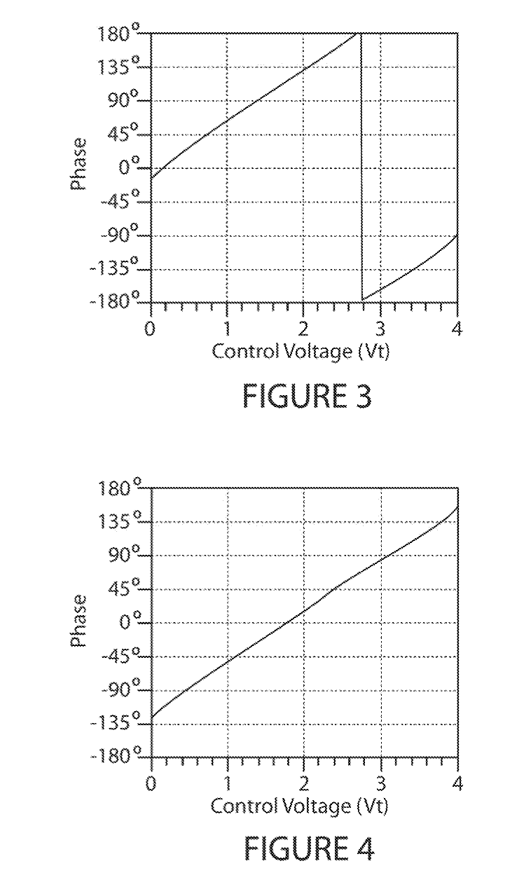

FIG. 3 shows that the actual phase shift angle of the voltage controlled SAW oscillator 10 in accordance with the present invention. FIG. 4 is a version of the graph/plot of FIG. 3 which has been normalized to remove the phase wrap and more accurately depict the improved linearity. More specifically, FIG. 4 shows that the phase shift angle of the voltage controlled SAW oscillator 10 is advantageously near zero at a control/tuning voltage (Vt) of about 1.8V.

While the invention has been taught with specific reference to one embodiment of an oscillator and, more specifically, a voltage controlled SAW oscillator, it is understood that someone skilled in the art will recognize that changes can be made in form and detail without departing from the spirit and the scope of the invention as defined in the appended claims. The described embodiment is to be considered in all respects only as illustrative of one embodiment and not restrictive.

Thus, for example, it is understood that the invention encompasses the embodiment where the phase shifter includes at least one high pass circuit coupled in series with and between a pair of low pass circuits. For another example, it is understood that the invention is applicable not only in a voltage controlled SAW oscillator but also in any other type of SAW oscillator with a SAW filter such as, for example, a frequency translator, or any other type of oscillator with any other type of filter such as, for example, a crystal filter, an LC filter, or a ceramic filter.

What is claimed is:

1. An oscillator comprising:
a filter; and
a phase shifter coupled to the filter, the phase shifter including at least one low pass circuit coupled to at least one high pass circuit.

2. The oscillator of claim 1 wherein the low pass circuit includes a pair of inductors coupled in series and a variable capacitor having one end coupled between the pair of inductors.

3. The oscillator of claim 2 wherein the high pass circuit includes a pair of variable capacitors coupled in series and an inductor having one end coupled between the pair of varactors.

4. The oscillator of claim 1 wherein the phase shifter includes a low pass circuit coupled in series between a pair of high pass circuits.

5. The oscillator of claim 1 wherein the oscillator is a voltage controlled surface acoustic wave oscillator and the filter is a surface acoustic wave filter.

6. An oscillator comprising at least a phase shifter including means for adjusting both negative and positive phase shift and centering the frequency of the oscillator.

7. The oscillator of claim 6 wherein the means for adjusting both negative and positive phase shift comprises at least a first low pass phase shifter circuit and at least a first high pass phase shifter circuit coupled together in series.

8. The oscillator of claim 7 wherein the first low pass phase shifter circuit includes a pair of inductors coupled in series and a variable capacitor coupled therebetween and the first high pass phase shifter circuit includes a pair of variable capacitors coupled in series and an inductor coupled therebetween.

9. The oscillator of claim 7 further comprising a second high pass phase shifter circuit coupled in series with the first low pass phase shifter circuit, the first low pass phase shifter circuit being located between the first and second high pass phase shifter circuits.

10. The oscillator of claim 6 wherein the oscillator is a voltage controlled surface acoustic wave oscillator including a surface acoustic wave filter.

11. A voltage controlled surface acoustic wave oscillator comprising at least a surface acoustic wave filter and a voltage controlled phase shifter, the voltage controlled phase shifter including at least first and second high pass circuits and at least a first low pass circuit coupled in series between the first and second high pass circuits, each of the first and second high pass circuits including at least a first variable capacitor and the first low pass circuit including at least a first inductor coupled in series with the first variable capacitor of the first high pass circuit and a second inductor coupled in series with the first variable capacitor of the second high pass circuit.

12. The voltage controlled surface acoustic wave oscillator of claim 11 wherein the first low pass circuit further includes a variable capacitor coupled at one end between the first and second inductors and coupled at the other end to ground and each of the first and second high pass circuits further includes a second variable capacitor and an inductor coupled at one end between the first and second variable capacitors and coupled at the other end to ground.

13. The voltage controlled surface acoustic wave oscillator of claim 11 further comprising an amplifier coupled to the voltage controlled phase shifter.

14. The voltage controlled surface acoustic wave oscillator of claim 12 further comprising a control voltage input circuit coupled to the second variable capacitor of each of the first and second high pass circuits.
